(19) United States
(12) Patent Application Publication
(10) Pub. No.: US 2012/0152738 A1
(43) Pub. Date: Jun. 21, 2012

(54) MAGNETRON ARRANGEMENT WITH A HOLLOW TARGET

(75) Inventors: Hans-Juergen HEINRICH, Grossroehrsdorf (DE); Harald GRUNE, Dresden (DE); Rolf RANK, Dresden (DE)

(73) Assignee: VON ARDENNE ANLAGENTECHNIK GMBH, Dresden (DE)

(21) Appl. No.: 13/332,601

(22) Filed: Dec. 21, 2011

(30) Foreign Application Priority Data
Dec. 21, 2010 (DE) 102010063685.1-54

(51) Int. Cl. C23C 14/35

(52) U.S. Cl. 204/298.12

(57) ABSTRACT

A magnetron arrangement includes a hollow target and a magnet system arranged in the hollow target with a magnet carrier and a magnet arrangement fitted on the magnet carrier. The magnet carrier includes at least two magnet carrier elements, which each have at least one cavity and each have at least one contact face on an outer side. The at least two magnet carrier elements are in touching contact with their contact faces and are fixedly connected to one another, and the cavities of the magnet carrier elements have no connection between them.

### CROSS REFERENCE TO RELATED APPLICATIONS

This application claims priority of German application 10 2010 063 685.1-54 filed on Dec. 21, 2010, the entire contents of which is hereby incorporated by reference herein.

### BACKGROUND ART

The invention relates to a magnetron arrangement with a hollow target.

In coating facilities, magnetron arrangements with hollow targets are used in order to increase the target material yield and to reduce coating costs. The hollow target is mounted on one or both sides on one or two holding devices, it being possible for the mounting arrangement to be such that the hollow target is rotatable. A magnet system is arranged in the hollow target of such magnetron arrangements, said magnet system having a magnetic field which causes electrons to be kept in the vicinity of the target surface. A plasma is concentrated in the region of high magnetic field intensity by the magnetic field. A negative cathode voltage applied to the target brings about ion bombardment by process gas ions on the target surface and therefore uniform deposition of the target material.

The magnet system consists of a magnet carrier with magnets fitted thereon, for example. The magnet system is arranged in the hollow target in a manner conforming to the process, for example rotatably or secured against rotation. The magnets are thus optimally held in the interior of the hollow target and are surrounded by cooling water. The volume that is filled with cooling water is comparatively large and low flow rates with low turbulences are produced at the inner faces of the hollow target which are to be cooled.

It is also known that the magnet carrier needs to be rigid in order that, even in the case of long hollow targets, for example hollow targets with a length of three to four meters, the distance between the magnets and the inner face of the hollow target remains constant, in order that the magnetic field is as uniform as possible over the outer side of the hollow target. If the magnet system is very rigid, however, its weight also increases. Many known magnet systems therefore subject the bearing points to stress owing to their high dead weight; this results in increased service complexity.

When a target is replaced, the magnet system needs to be removed from the used hollow target and introduced into the new hollow target. For construction-related reasons, sealing faces are located on the end sides of the hollow targets. Said sealing faces are at risk of impact when the target is replaced. Magnet systems for example those consisting of stainless steel, cause damage in the event of a collision with an end-side sealing face of the hollow target, and this damage can result in subsequent leaks of the magnetron arrangement.

US 2006/0157346 A1 has disclosed a magnetron device with a hollow target, with a magnet carrier arranged in the interior thereof, said magnet carrier being in the form of an extruded, double-walled tube consisting of aluminum, with the inner tube being connected by six ribs to the outer tube, which bears the magnet system on its outer side.

U.S. Pat. No. 5,571,393 B has disclosed a magnet housing, in which a magnet arrangement and a coolant line are accommodated in one housing, the housing being formed from two housing halves which are connected to one another and which enclose a common cavity. The coolant is conveyed in the coolant line, which is arranged in the cavity of the housing, from a first end of the hollow target to a second end, fed there into the interspace between the housing and the hollow target and in this interspace fed back to the first end of the hollow target, the inner face of the hollow target being cooled in the process. The distance between the magnets and the hollow target is in this case relatively great, however, because the wall of the housing is located in between.

WO 2009/138348 A1 has disclosed a magnet system, in which the magnets are arranged on or in an integral carrier element, for example an extruded aluminum profile, which has high flexural rigidity given a low weight. However, carrier elements consisting of aluminum alloys and having coolant flowing around them need to be provided with a passivation layer or an elastomer layer in order that they are protected from corrosion. When this protective layer becomes damaged, there is the risk of corrosive attack on the carrier element. Furthermore, the proposed profile has a complex cross section, which entails relatively high manufacturing costs.

One object therefore consists in providing a magnetron arrangement with a magnet system which manages with a low quantity of coolant. A further object consists in guiding the coolant such that as great a cooling power as possible is achieved. A further object consists in specifying a magnetron arrangement with a magnet carrier which is insensitive to corrosion. A further object consists in providing a magnet carrier system which has a high flexural rigidity for reliable operation of the magnetron arrangement independently of the installation position. A further object consists in reducing the weight of the magnet system in order to relieve the bearing points of load. A further object consists in increasing the fitting safety when introducing and removing the magnet carrier system into and from the hollow target in order to avoid damage to sealing faces.

### BRIEF SUMMARY OF THE INVENTION

Therefore, a magnetron arrangement is proposed which comprises a hollow target and a magnet system arranged in the hollow target with a magnet carrier and a magnet arrangement fitted on the magnet carrier, the magnet carrier comprising at least two magnet carrier elements, which each have at least one cavity and each have at least one contact face on the outer side, the at least two magnet carrier elements being in touching contact with their contact faces and being fixedly connected to one another, and the cavities of the magnet carrier elements having no connection between them.

The proposed device also consists of at least two elongate magnet carrier elements which are connected to one another and which each have at least one elongate cavity, it being possible for these cavities to be used for different purposes, as will be explained further below. The individual cavities are delimited from one another, i.e. there is no communicating connection between them, with the result that a dedicated use of each cavity for a specific purpose is possible. At the same time, the magnet carrier elements each per se have a relatively simple design, with the result that their production is simple and inexpensive. The magnet carrier elements are connected to one another at contact faces, with the result that a plurality of simple cross sections together form a complex cross section with a high flexural rigidity and a low weight.

In this case, provision can be made for at least one cavity of a magnet carrier element to be a coolant line, and one development can provide that the coolant line has coolant outlets along the magnet carrier element. Owing to the use of the cavity of a magnet carrier element as coolant line, it is possible to dispense with separate coolant lines, while the arrangement of coolant outlets makes it possible to feed coolant into the hollow target uniformly and therefore permits efficient cooling of the hollow target.

Provision can furthermore be made for at least one cavity of a magnet carrier element to be filled with a foamed polymer. Filling the cavity of the magnet carrier element with a foamed polymer firstly contributes to increasing the flexural rigidity of the magnet carrier, and secondly the ingress of coolant into the cavity is prevented if a leak should occur.

In another configuration, provision is made for the magnet arrangement to be arranged in at least one cavity of a magnet carrier element. Alternatively, the magnet arrangement can be arranged on the outer side of a magnet carrier element. By virtue of attaching the magnet arrangement in a cavity which is sealed off with respect to other, for example coolant-carrying cavities, the magnet arrangement is well protected from corrosion. On the other hand, by attaching the magnet arrangement to the outer side of a magnet carrier element, the magnetic field strength on the outside of the hollow target is only weakened to a minimal extent and the magnet arrangement itself is cooled optimally. For this purpose, the magnet arrangement can be provided with an anti-corrosion coating, for example.

The magnet carrier element can have, for example, a pushed-in portion of an outer face which accommodates the magnet arrangement and, given a suitable configuration of the pushed-in portion, partially surrounds the magnet arrangement. A pushed-in portion is intended in this case to refer to a subarea of the outer face of a magnet carrier element which, when viewed from the outside, represents a depression. In another configuration, such a pushed-in portion which accommodates the magnet arrangement is formed by two or more adjoining magnet carrier elements, as will be explained in more detail in particular with reference to the exemplary embodiments.

A further configuration envisages that at least one magnet carrier element consists of a fiber composite material. Although in general there are provisos with respect to the use of polymers in magnetron arrangements, it has surprisingly been shown that they can be used with good results if effective cooling is ensured and polymers are used which are not attacked by the coolant used. Particularly suitable examples have proven to be fiber composite materials, for example with resins consisting of polyester, vinyl ester, epoxy or acryl with reinforcing fibers consisting of glass, carbon or aramid-Kevlar.

In accordance with a further configuration, the magnet carrier elements are adhesively bonded to one another at their contact faces. In particular in the case of full-area adhesive bonding of the magnet carrier elements at the contact faces, this results in a marked increase in the flexural rigidity of a magnet carrier comprising two or more magnet carrier elements. In addition or as an alternative, the magnet carrier elements can also be connected to one another by screws, rivets or similar means. Such similar means can include, for example, form-fitting connecting elements which are arranged on the contact faces, i.e. the outer sides of the magnet carrier elements and can be connected to one another. Likewise in addition or as an alternative, the magnet carrier elements can also be connected to one another by rings or tensioning straps which surround the magnet carrier elements from the outside.

Provision can furthermore be made for the contact faces of the magnet carrier elements to have pushed-in portions, which form a further cavity. The term pushed-in portion is in this case likewise intended to be understood in the sense explained above. The pushed-in portions of the mutually facing outer faces of two or more magnet carrier elements thus form an elongate cavity, which is located between the two or more magnet carrier elements and therefore has no connection to a cavity of a magnet carrier element.

A bar-shaped reinforcing element can be arranged in this further cavity, for example. Such a bar-shaped reinforcing element can be, for example, a bar with a round or rectangular cross section, for example. This reinforcing element can, in a further configuration, likewise have an elongate cavity, for example in order to conduct coolant or accommodate an electrical cable.

### BRIEF DESCRIPTION OF THE DRAWING FIGURES

Exemplary embodiments of the magnet carriers described will be explained in more detail below with reference to figures, in which:

FIG. 1 shows a cross section through a magnetron arrangement with two magnet carrier elements without any pushed-in portions of the contact faces,

FIG. 2 shows a cross section through a magnetron arrangement with three magnet carrier elements which have pushed-in portions of the contact faces which form a cavity,

FIG. 3 shows a cross section through a magnetron arrangement with two magnet carrier elements which have pushed-in portions of the contact faces which form a cavity, in which a reinforcing element is arranged,

FIG. 4 shows a cross section through a magnetron arrangement with two magnet carrier elements which have pushed-in portions of the contact faces which form a cavity.

### DETAILED DESCRIPTION

All of the exemplary embodiments illustrate a hollow target 1 which is hollow-cylindrical in cross section and in which a layer of a target material 12 is arranged on the outer side of a carrier structure 11.

In each case one magnet carrier 3, which comprises two or more magnet carrier elements 31 which are connected to one another and are connected to one another at contact faces 34, is arranged in the interior of the hollow target 1. A magnet arrangement 2, which comprises a magnet holder 21 and a plurality of magnets 22 is fastened to the outer side of the magnet carrier 3, with the result that the magnets 22 are arranged in the vicinity of the inner face of the hollow target 1. The magnet holder 21 in the exemplary embodiments is merely optional; it goes without saying that the magnets 22 could also be fitted directly to a magnet carrier element.

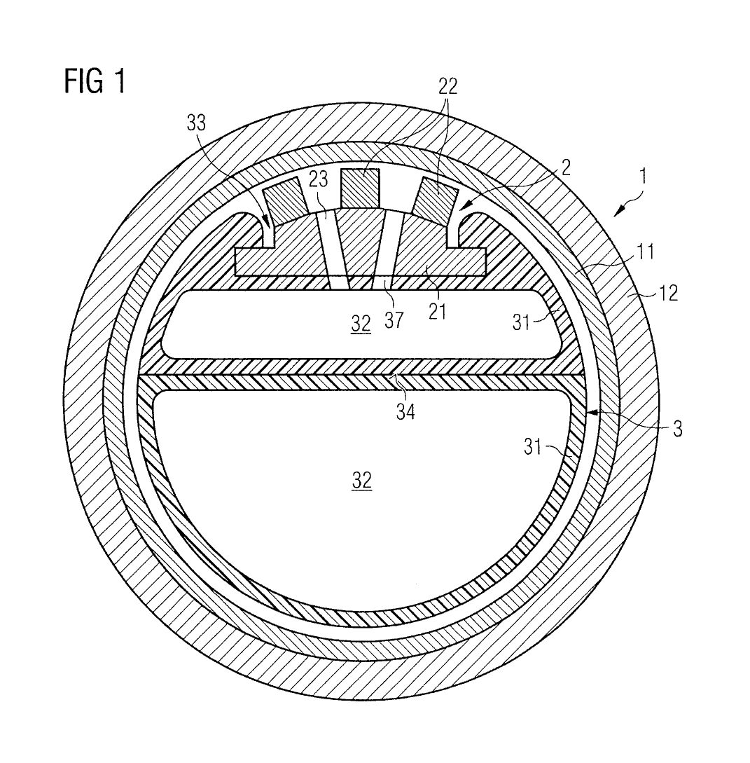

FIG. 1 shows an exemplary embodiment in which two magnet carrier elements 31 each have a planar contact face, the magnet carrier elements 31 being in touching contact with one another and being connected to one another at said contact faces, for example by means of adhesive bonding. Each magnet carrier element 31 has a cavity 32, which is separated from the cavity 32 of the other magnet carrier element 31, and which can be used as coolant line, receptacle for electrical lines or the like. Furthermore, these cavities 32 can be filled with a foamed polymer.

In the exemplary embodiment illustrated, the plane of separation between the two magnet carrier elements 31 runs horizontally and the magnet arrangement 2, which comprises a magnet holder 21 and magnets 22, is fastened to the upper of the two magnet carrier elements 31. For this purpose, the magnet carrier element 31 has a pushed-in portion 33, in which the magnet arrangement 2 is held. Furthermore, the upper (in the selected illustration) magnet carrier element 31 has a plurality of coolant outlets 37, which, with correspondingly arranged coolant outlets 23 of the magnet holder 21, ensure that the coolant guided in the cavity 32 is emitted to the interior of the hollow target 1 over the entire length of the hollow target 1 in the region of the magnets 22.

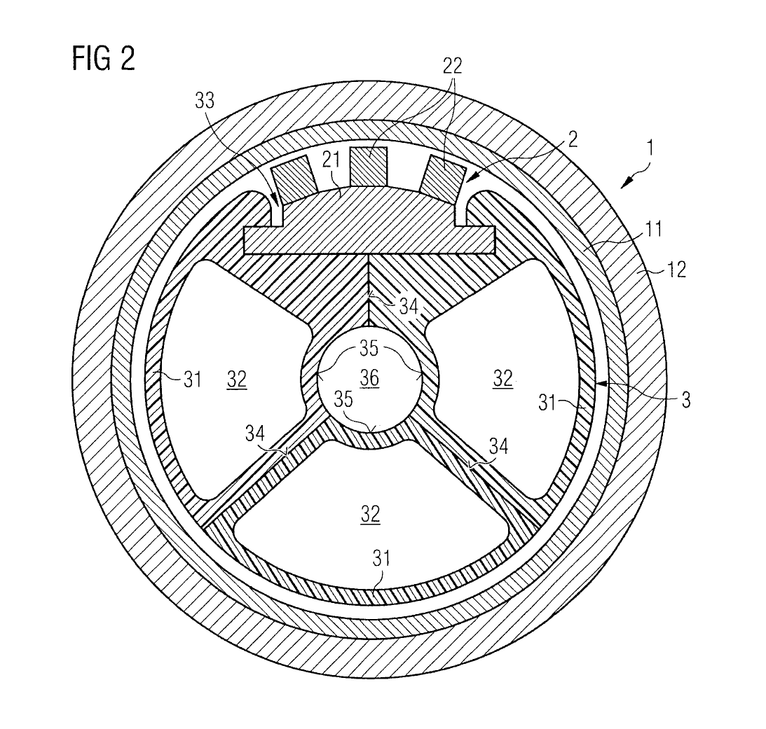

FIG. 2 shows an exemplary embodiment in which the magnet carrier 3 comprises three magnet carrier elements 31, which each have two contact faces 34, at which they are connected to an adjacent magnet carrier element 31. These contact faces have pushed-in portions 35, by means of which a central cavity 36 is formed between the magnet carrier elements 31, it being possible for said central cavity to likewise act as coolant line or for similar purposes.

The magnet arrangement which in turn comprises a magnet holder 21 and magnets 22 fitted thereto, is held by two adjacent magnet carrier elements 31, which each have a pushed-in portion 33 on their outer sides. These two pushed-in portions 33 interact with one another as a receptacle for the magnet arrangement 2.

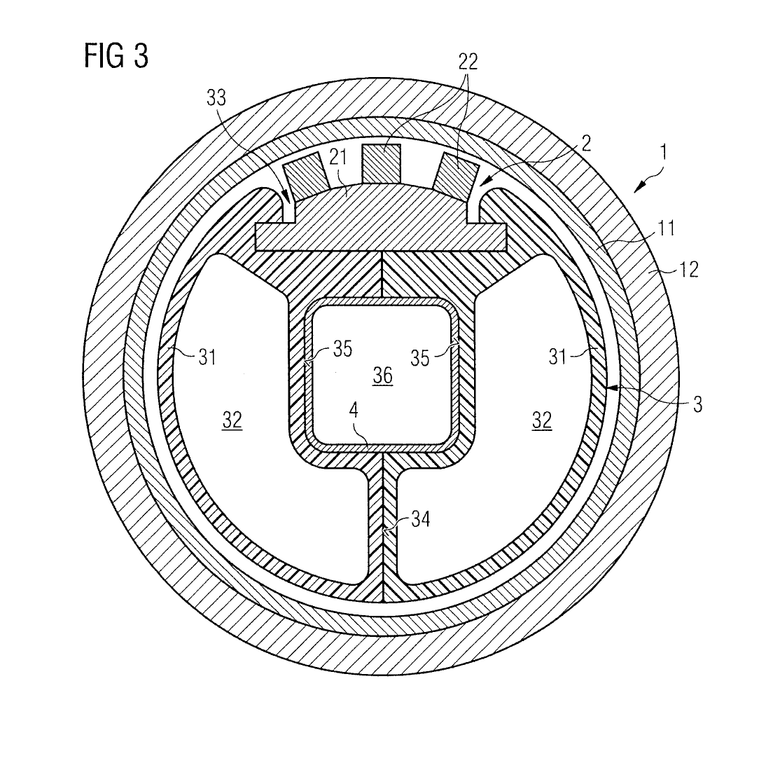

In the exemplary embodiment shown in FIG. 3, two magnet carrier elements 31 are connected to one another at contact faces 34 in such a way that the plane of separation in the selected illustration runs vertically and the magnet arrangement in turn is held in two interacting pushed-in portions 33 on the outer sides of the two magnet carrier elements 31.

The contact faces 34 of the two magnet carrier elements 31 each have a pushed-in portion 35, which together form a centrally arranged cavity 36 which has a rectangular cross section. A bar-shaped reinforcing element 4 with a corresponding, rectangular cross section is arranged in this cavity 36. This is a rectangular hollow profile which can be used as coolant line or for similar purposes.

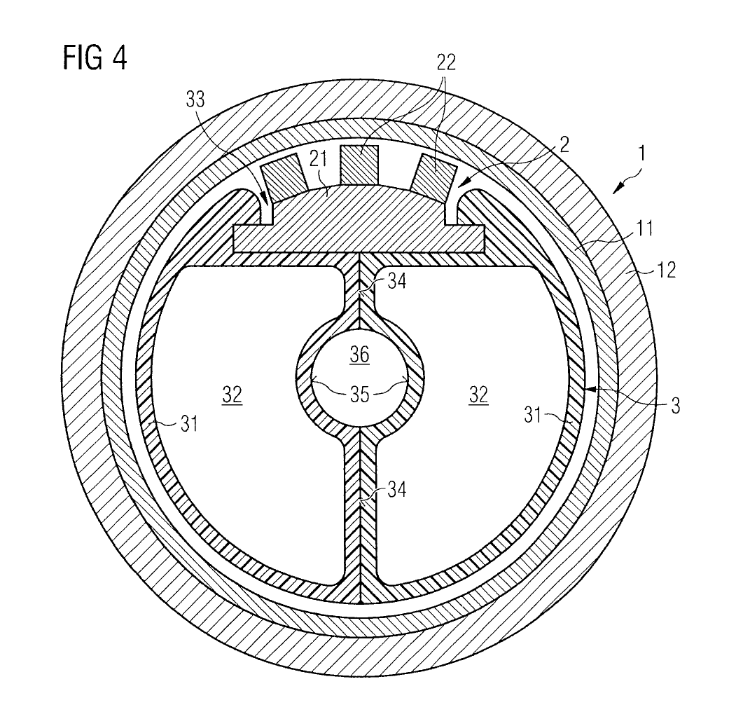

Similarly, the magnet carrier 3 in the exemplary embodiment shown in FIG. 4 comprises two magnet carrier elements 31, in which the contact faces 34 in the selected illustration form a vertical plane of separation. The magnet arrangement is also held in two interacting pushed-in portions 33 on the outer sides of the two magnet carrier elements 31.

The pushed-in portions 35 of the contact faces 34 together form a cavity 36 with a circular cross section, in which, in the exemplary embodiment, no reinforcing element is arranged, however.

1. Magnetron arrangement, comprising a hollow target and a magnet system arranged in the hollow target with a magnet carrier and a magnet arrangement fitted on the magnet carrier, the magnet carrier comprising at least two magnet carrier elements, which each have at least one cavity and each have at least one contact face on an outer side, the at least two magnet carrier elements being in touching contact with their contact faces and being fixedly connected to one another, and cavities of the magnet carrier elements having no connection between them.

2. Magnetron arrangement according to claim 1, wherein at least one cavity of a magnet carrier element comprises a coolant line.

3. Magnetron arrangement according to claim 2, wherein the coolant line has coolant outlets along the magnet carrier element.

4. Magnetron arrangement according to claim 1, wherein at least one cavity of a magnet carrier element is filled with a foamed polymer.

5. Magnetron arrangement according to claim 1, wherein the magnet arrangement is arranged in at least one cavity of a magnet carrier element.

6. Magnetron arrangement according to claim 1, wherein the magnet arrangement is arranged on the outer side of a magnet carrier element.

7. Magnetron arrangement according to claim 1, wherein at least one magnet carrier element comprises a fiber composite material.

8. Magnetron arrangement according to claim 1, wherein the magnet carrier elements are adhesively bonded to one another at their contact faces.

9. Magnetron arrangement according to claim 1, wherein the contact faces of the magnet carrier elements have pushed-in portions which form a further cavity.

10. Magnetron arrangement according to claim 9, further comprising a bar-shaped reinforcing element arranged in the further cavity.
